(19) United States
(12) Patent Application Publication
(10) Pub. No.: US 2020/0321272 A1
(43) Pub. Date: Oct. 8, 2020

(54) MODULE WITH BALL GRID ARRAY HAVING INCREASED DIE AREA

(71) Applicant: SKYWORKS SOLUTIONS, INC., Woburn, MA (US)

(72) Inventors: Bipul AGARWAL, Irvine, CA (US); Howard E. CHEN, Anaheim, CA (US); Mahitha VALLAMPATI RAGHURAM, Irvine, CA (US); Shaul BRANCHEVSKY, Mission Viejo, CA (US)

(21) Appl. No.: 16/812,270

(22) Filed: Mar. 7, 2020

Related U.S. Application Data
(60) Provisional application No. 62/815,342, filed on Mar. 7, 2019.

(51) Int. Cl. H01L 23/498; H01L 23/66; H01L 21/48

(52) U.S. Cl. CPC H01L 23/49816; H01L 2223/6677; H01L 21/4853; H01L 23/66

(57) ABSTRACT

Module with ball grid array having increased die area. In some embodiments, a packaged module can include a packaging substrate having side edges, and a grid array arranged on an underside of the packaging substrate. The grid array can include a plurality of mounting features arranged in at least two rows, with each row being along the respective side edge of the packaging substrate, such that at least one side edge of the packaging substrate is without a row of mounting features. The packaged module can further include a component mounted to the underside of the packaging substrate and within a mountable area defined by the at least two rows of mounting features and the at least one side edge of the packaging substrate without the row of mounting features.

### CROSS-REFERENCE TO RELATED APPLICATION(S)

This application claims priority to U.S. Provisional Application No. 62/815,342 filed Mar. 7, 2019, entitled MODULE WITH BALL GRID ARRAY HAVING INCREASED DIE AREA, the disclosure of which is hereby expressly incorporated by reference herein in its respective entirety.

### BACKGROUND

### Field

The present disclosure relates to packaged radio-frequency (RF) modules having ball grid array.

### Description of the Related Art

In wireless applications, a radio-frequency (RF) module can be implemented as a packaged module. Such a module can include mounting and/or connectivity functionalities provided by features such as a ball grid array (BGA).

### SUMMARY

In accordance with a number of implementations, the present disclosure relates to a packaged module that includes a packaging substrate having side edges, and a grid array arranged on an underside of the packaging substrate. The grid array includes a plurality of mounting features arranged in at least two rows, with each row along the respective side edge of the packaging substrate, such that at least one side edge of the packaging substrate is without a row of mounting features. The packaged module further includes a component mounted to the underside of the packaging substrate and within a mountable area defined by the at least two rows of mounting features and the at least one side edge of the packaging substrate without the row of mounting features.

In some embodiments, the grid array can be a ball grid array, and the mounting features can include solder balls. In some embodiments, the mounting features can include conductive pillars such as conductive columns or conductive posts.

In some embodiments, the at least two rows of mounting features can include two opposing rows along the two opposing side edges of the packaging substrate. The at least one side edge of the packaging substrate without mounting features can include either or both of the other two opposing side edges of the packaging substrate.

In some embodiments, the at least two rows of mounting features can include two adjacent rows along the corresponding adjacent side edges of the packaging substrate.

In some embodiments, the packaged module can further include a radio-frequency circuit implemented in one or more semiconductor die mounted on an upper side of the packaging substrate. The radio-frequency circuit can be configured to support, for example, one or more low-band cellular frequency ranges.

In some embodiments, the packaged module can further include an overmold configured to substantially encapsulate the one or more semiconductor die mounted on the upper side of the packaging substrate. In some embodiments, the packaged module can further include an electromagnetic shield configured to provide shielding functionality for at least a portion of the radio-frequency circuit.

In some embodiments, the component mounted to the underside of the packaging substrate can include a die.

In some implementations, the present disclosure relates to a method for fabricating a packaged module. The method includes providing or forming a packaging substrate having side edges, and forming a grid array on an underside of the packaging substrate, such that the grid array includes a plurality of mounting features arranged in at least two rows, with each row along the respective side edge of the packaging substrate, such that at least one side edge of the packaging substrate is without a row of mounting features. The method further includes mounting a component to the underside of the packaging substrate and within a mountable area defined by the at least two rows of mounting features and the at least one side edge of the packaging substrate without the row of mounting features.

In some embodiments, the forming of the grid array can include forming a ball grid array.

In some teachings, the present disclosure relates to a wireless device that includes a transceiver and a radio-frequency module in communication with the transceiver and configured to process a signal. The radio-frequency module includes a packaging substrate having side edges, and a grid array arranged on an underside of the packaging substrate and including a plurality of mounting features arranged in at least two rows, with each row along the respective side edge of the packaging substrate, such that at least one side edge of the packaging substrate is without a row of mounting features. The radio-frequency module further includes a component mounted to the underside of the packaging substrate and within a mountable area defined by the at least two rows of mounting features and the at least one side edge of the packaging substrate without the row of mounting features. The wireless device further includes an antenna in communication with the radio-frequency module and configured to support operation of the wireless device.

In some embodiments, the signal can have a frequency in a low-band cellular frequency range.

According to some implementations, the present disclosure relates to a packaging substrate assembly that includes a packaging substrate having side edges. The packaging substrate assembly further includes a grid array arranged on an underside of the packaging substrate and including a plurality of mounting features arranged in at least two rows, with each row along the respective side edge of the packaging substrate, such that at least one side edge of the packaging substrate is without a row of mounting features.

In some embodiments, the grid array can be a ball grid array, and the mounting features can include solder balls.

In some embodiments, the mounting features can include conductive pillars such as conductive columns or conductive posts.

In some embodiments, the at least two rows of mounting features can include two opposing rows along the two opposing side edges of the packaging substrate. In some embodiments, the at least two rows of mounting features can include two adjacent rows along the corresponding adjacent side edges of the packaging substrate.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1A shows a side sectional view of an example dual-sided module having a ball grid array (BGA) on its underside.

FIG. 1B shows an underside view of the dual-sided module of FIG. 1A.

FIG. 2A shows a side sectional view of another example dual-sided module having a ball grid array (BGA) on its underside.

FIG. 2B shows an underside view of the dual-sided module of FIG. 2A.

FIG. 3 shows an example dual-sided module having a ball grid array (BGA) on its underside configured to provide an increased mountable area for one or more underside components.

FIG. 4 shows another example dual-sided module having a ball grid array (BGA) on its underside configured to provide an increased mountable area for one or more underside components.

FIG. 5 shows yet another example dual-sided module having a ball grid array (BGA) on its underside configured to provide an increased mountable area for one or more underside components.

FIG. 6 shows yet another example dual-sided module having a ball grid array (BGA) on its underside configured to provide an increased mountable area for one or more underside components.

FIG. 7 shows yet another example dual-sided module having a ball grid array (BGA) on its underside configured to provide an increased mountable area for one or more underside components.

FIG. 8 shows an underside of a packaged module having a packaging substrate similar to the example of FIG. 3, where a component such as a die is shown to be mounted within an increased mountable area.

FIG. 9 shows an underside of a packaged module having a packaging substrate similar to the example of FIG. 8, where more than one component can be mounted within an increased mountable area.

FIG. 10 shows an underside of a packaging substrate having an increased mountable area similar to the example of FIG. 3, but where structures such as pillars can be utilized instead of solder balls.

### DETAILED DESCRIPTION OF SOME EMBODIMENTS

The headings provided herein, if any, are for convenience only and do not necessarily affect the scope or meaning of the claimed invention.

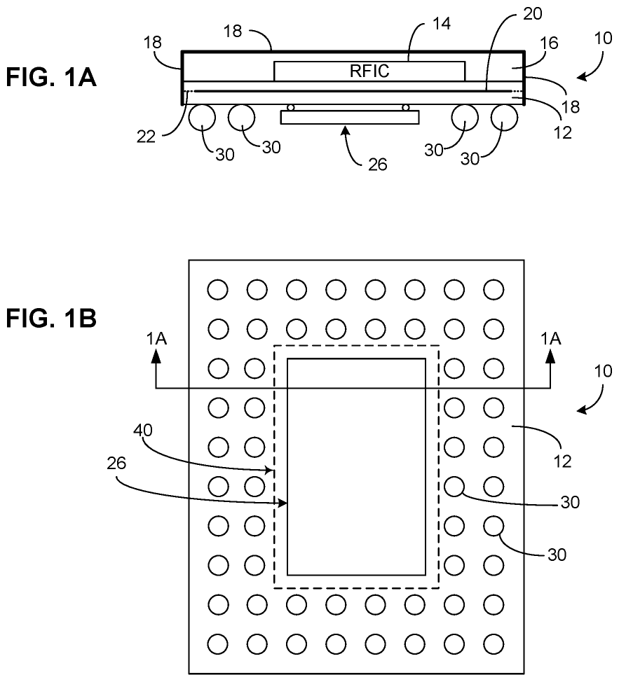

FIGS. 1A and 1B show an example dual-sided module 10 having a ball grid array (BGA) on its underside. FIG. 1B shows an underside view of the module 10, and FIG. 1A shows a side sectional view as indicated. More particularly, the module 10 includes a packaging substrate 12 with a radio-frequency (RF) circuit (collectively indicated as 14) implemented on its first side (e.g., upper side), and one or more components (collectively indicated as 26) mounted on its second side (e.g., underside). The RF circuit 14 on the upper side of the packaging substrate 12 can include, for example, one or more semiconductor die, and/or one or more surface-mount technology (SMT) devices. The underside component(s) 26 can include, for example, one or more semiconductor die.

In the example module 10 of FIGS. 1A and 1B, an overmold 16 is shown to be implemented on the upper side of the packaging substrate 12 so as to encapsulate the RF circuit 104. Further, the upper surface of the overmold 16 and the side walls of the module 10 are shown to have a conductive layer 18 (e.g., a conformal conductive layer) that is electrically connected to a ground plane 20 within the packaging substrate 12, through an electrical connection depicted as 22. Accordingly, the conductive layer 18 and the ground plane 20 generally define an internal volume, and provide RF shielding functionality between the internal volume and external location(s). In some embodiments, the module 10 may or may not include additional shielding functionality (e.g., intra-module shielding between regions within the internal volume). In some embodiments, the module 10 may or may not include any shielding functionality (e.g., the conductive layer 18).

In the example of FIGS. 1A and 1B, the BGA is shown to include a plurality of solder balls 30 arranged so as to provide an underside volume dimensioned to allow mounting of the underside component(s) 26. Such underside component(s) can be mounted to the underside of the packaging substrate 12 with or without an underfill.

In the example of FIGS. 1A and 1B, some of the solder balls 30 of the BGA are shown to be arranged along an inner perimeter, and the remaining solder balls 30 are shown to be arranged along an outer perimeter. Accordingly, a mountable area 40 is defined within the inner perimeter of solder balls. Typically, there is a keep-out space between a row of solder balls and the corresponding side of the mountable area 40. Accordingly, the underside component 26 needs to have lateral dimensions that allow the component 26 to fit within the mountable area 40.

In the example of FIGS. 1A and 1B, the solder balls 30 can provide electrical connections for the module 10, including, for example, grounding connection(s), signal connection(s), and/or power connection(s).

Among others, additional details related to dual-sided modules having BGAs, as well as related methods and products, can be found in PCT Publication No. WO/2018/067578 titled DUAL-SIDED RADIO-FREQUENCY PACKAGE WITH OVERMOLD STRUCTURE, which is expressly incorporated by reference in its entirely, and its disclosure is to be considered part of the specification of the present application.

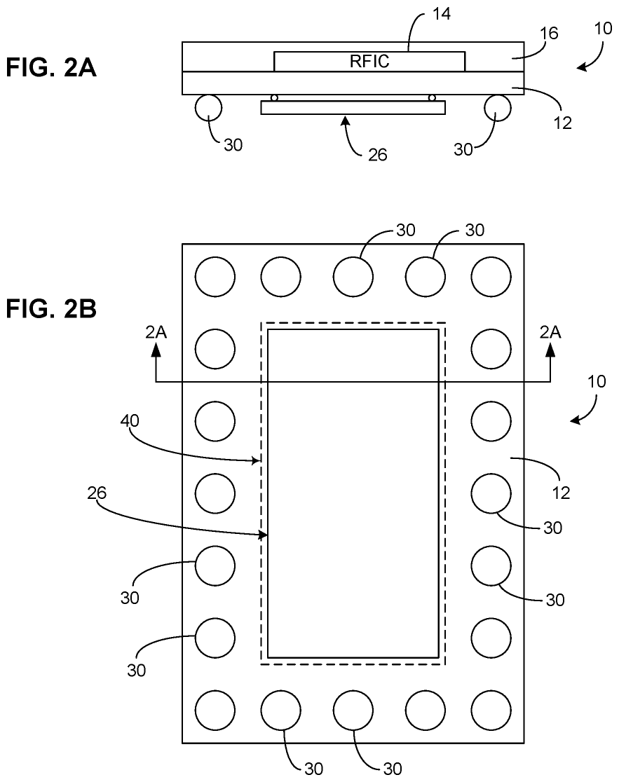

FIGS. 2A and 2B show another example dual-sided module 10 having a ball grid array (BGA) on its underside. FIG. 2B shows an underside view of the module 10, and FIG. 2A shows a side sectional view as indicated. In the example of FIGS. 2A and 2B, the module 10 is depicted as not including a conformal shielding functionality; however, it will be understood that such a module may or may not include a shielding functionality.

The module 10 of FIGS. 2A and 2B can be similar to the module 10 of FIGS. 1A and 1B, other than the BGA of FIGS. 2A and 2B having solder balls 30 arranged along a single perimeter. Accordingly, in the example of FIGS. 2A and 2B, a mountable area 40 is defined within the single perimeter of solder balls. Thus, an underside component 26 needs to have lateral dimensions that allow the component 26 to fit within the mountable area 40.

In some embodiments, an assembly of a packaging substrate and a BGA can be configured such that the BGA includes solder balls arranged so that at least one side of a resulting mountable area is not constrained by solder balls. In such a configuration, the side of the mountable area not constrained by solder balls can extend towards the corresponding side edge of the packaging substrate, thereby increasing the mountable area. Accordingly, a larger underside component such as a die can be mounted to the underside of the packaging substrate having given lateral dimensions.

It is noted that in some embodiments, if a die having given lateral dimensions is being mounted to the underside of a packaging substrate, the foregoing mountable area can also allow one or more of the lateral dimensions of the corresponding packaging substrate to be smaller than that/those of a packaging substrate having a full perimeter of solder balls.

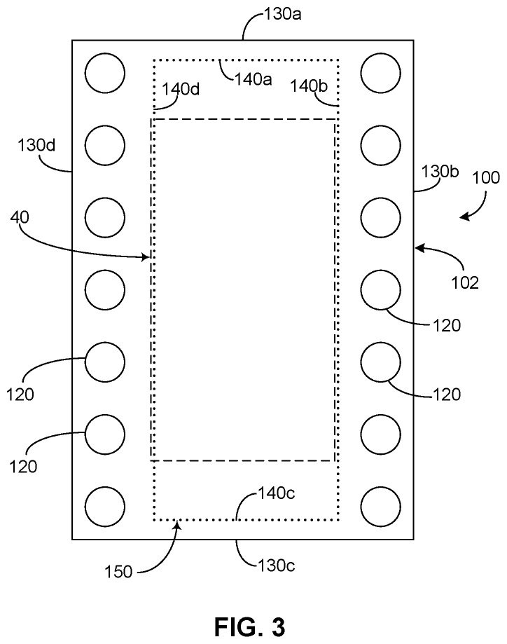

FIG. 3 shows an underside of an example packaging substrate 102 having a BGA with a plurality of solder balls 120. It will be understood that such solder balls can provide electrical connections including, for example, grounding connection(s), signal connection(s), and/or power connection(s). It will also be understood that the packaging substrate 102 can be a part of a packaged module 100 such as a dual-sided module with ball grid array (DSBGA), or a separate assembly that can be utilized to form a packaged module.

In the example of FIG. 3, the packaging substrate 102 is shown to have a rectangular shape with four side edges 130a, 130b, 130c, 130d, and the BGA is shown to include a row of solder balls 120 along each of the opposing side edges 130b, 130d. Accordingly, a mountable area 150 can have a generally rectangular shape having sides 140a (corresponding to the side edge 130a), 140b (corresponding to the side edge 130b), 140c (corresponding to the side edge 130c), and 140d (corresponding to the side edge 130d). Each of the opposing sides 140b, 140d of the mountable area 150 can be separated from the respective row of solder balls based on a corresponding keep-out dimension. Each of the opposing sides 140a, 140c of the mountable area 150 can be separated from the respective side edge of the packaging substrate 102 based on a corresponding keep-out dimension. It will be understood that the keep-out dimension associated with a row of solder balls may or may not be the same as the keep-out dimension associated with a side edge of the packaging substrate.

Configured in the foregoing manner, one can see that the mountable area 150 is larger than a mountable area 40 resulting from a configuration where a BGA includes a full perimeter of solder balls (e.g., the BGA of FIGS. 2A and 2B). More particularly, and assuming that the lateral dimensions of the packaging substrate 12 of FIG. 2B are similar to the lateral dimensions of the packaging substrate 102 of FIG. 3 (and the respective solder balls are similarly dimensioned), the mountable area 150 can have a similar dimension for the sides 140a, 140c as the corresponding sides of the mountable area 40, and an increased dimension for the sides 140b, 140d when compared to the corresponding sides of the mountable area 40.

In the example of FIG. 3, two opposing rows of solder balls are provided, and the other two opposing sides of a packaging substrate do not have solder balls that constrain a mountable area such as a rectangular shaped mountable area. Such two opposing rows of solder balls can allow the resulting module to be mounted to, for example, a circuit board in a stable manner. Thus, in some embodiments, it is preferable to have at least two rows of solder balls.

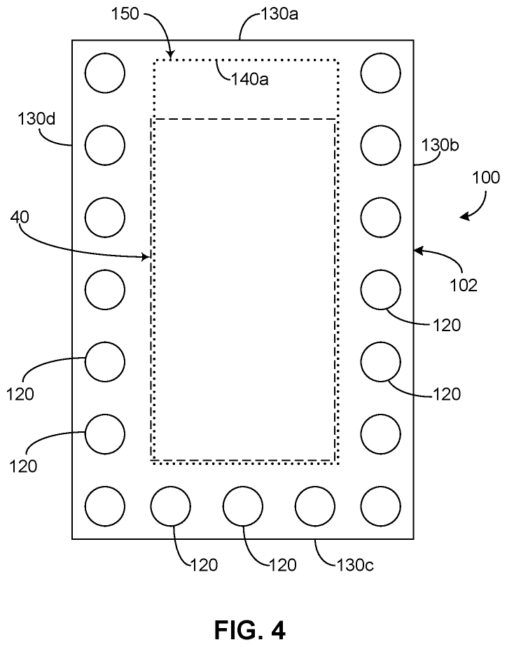

For example, FIG. 4 shows an underside of a packaging substrate 102 having a BGA with solder balls 120 arranged along each of three side edges 130b, 130b, 130d. Accordingly, a mountable area 150 can have a generally rectangular shape having an increase in area along the solder ball-less side edge 130a.

In the example of FIG. 4, the mountable area 150 has an area that is greater than a mountable area 40 resulting from a configuration where a BGA includes a full perimeter of solder balls (e.g., the BGA of FIGS. 2A and 2B), but less than the mountable area 150 of the example of FIG. 3. However, such an increase in mountable area may be desirable in some applications.

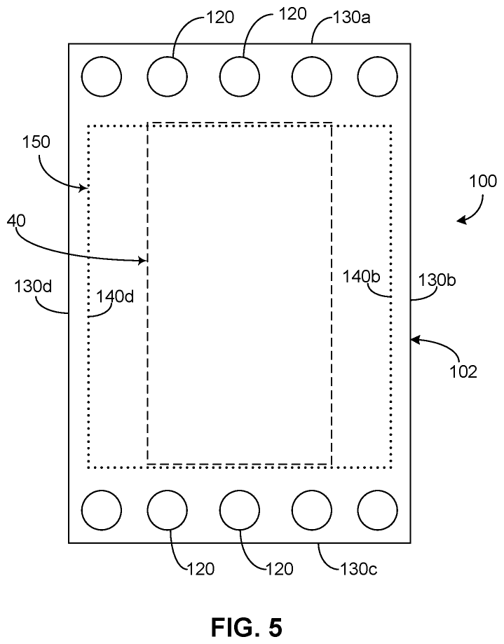

In another example, FIG. 5 shows an underside of a packaging substrate 102 having a BGA with solder balls 120 arranged along each of two opposing side edges 130a, 130c. Accordingly, a mountable area 150 can have a generally rectangular shape having an increase in area along each of the solder ball-less side edges 130b, 130d.

The example of FIG. 5 is similar to the example of FIG. 3 in the sense that solder balls are arranged along two opposing side edges of a packaging substrate. In FIG. 3, such two opposing side edges with solder balls are longer sides of the rectangular shape, and in FIG. 5, the two opposing side edges with solder balls are shorter sides of the rectangular shape. Thus, depending on a desired aspect ratio of an increased mountable area, either of the two examples can be utilized.

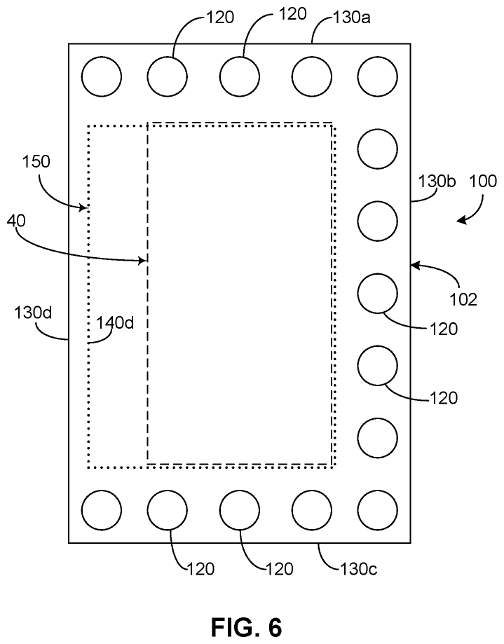

In yet another example, FIG. 6 shows an underside of a packaging substrate 102 having a BGA with solder balls 120 arranged along each of three side edges 130a, 130b, 130c. Accordingly, a mountable area 150 can have a generally rectangular shape having an increase in area along the solder ball-less side edge 130d.

The example of FIG. 6 relative to FIG. 5 is similar to the example of FIG. 4 relative to FIG. 3. Thus, depending on a desired aspect ratio of an increased mountable area, either of the two examples of FIGS. 6 and 4 can be utilized.

In the examples of FIGS. 3-6, the solder balls are arranged to include two opposing rows. In some embodiments, solder balls can be arranged along two adjacent rows, and the other pair of two adjacent rows can be without solder balls so as to provide respective increased areas.

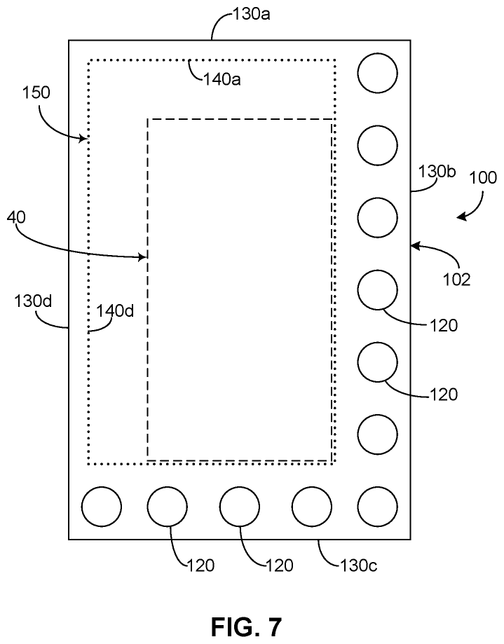

For example, FIG. 7 shows an underside of a packaging substrate 102 having a BGA with solder balls 120 arranged along each of two adjacent side edges 130b, 130c. Accordingly, a mountable area 150 can have a generally rectangular shape having an increase in area along each of the solder ball-less side edges 130d, 130a.

In the example of FIG. 7, the two solder balls arranged in the adjacent rows (e.g., at 90 degrees) can still allow the resulting module to be mounted in a stable manner.

As described herein, any one of the examples of FIGS. 3-7 can provide an increased mountable area on the underside of a packaging substrate with a BGA. As also described herein, such a packaging substrate can be utilized to form a packaged module.

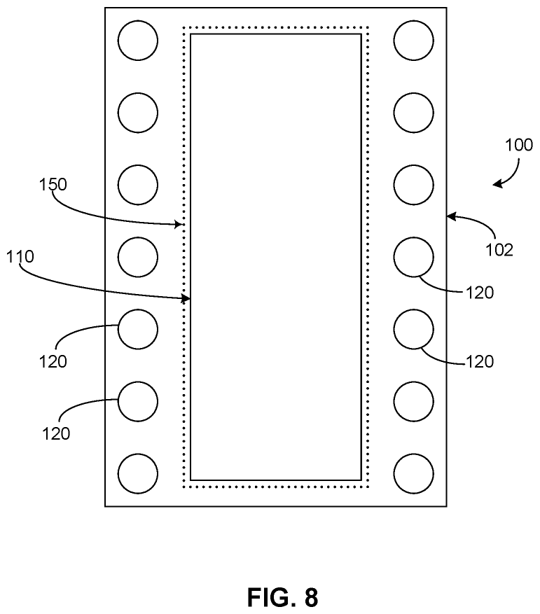

For example, FIG. 8 shows an underside of a packaged module 100 having a packaging substrate similar to the example of FIG. 3. In FIG. 8, a component 110 such as a die is shown to be mounted within an increased mountable area 150. Thus, in some embodiments, such a die can be desirably larger than, for example, the die 26 of FIG. 2B (assuming that lateral dimensions of the respective packaging substrates are similar).

In some embodiments, and assuming that lateral dimensions of the die 26 of FIG. 2B and the die 110 of FIG. 8 are similar, one can also see that the increased mountable area 150 of FIG. 8 can allow the packaging substrate 102 (and thus the module 100) to be desirably smaller than that of FIG. 2B. More particularly, the length dimension of the packaging substrate 102 of FIG. 8 can be smaller than the length dimension of the packaging substrate 12 of FIG. 2B.

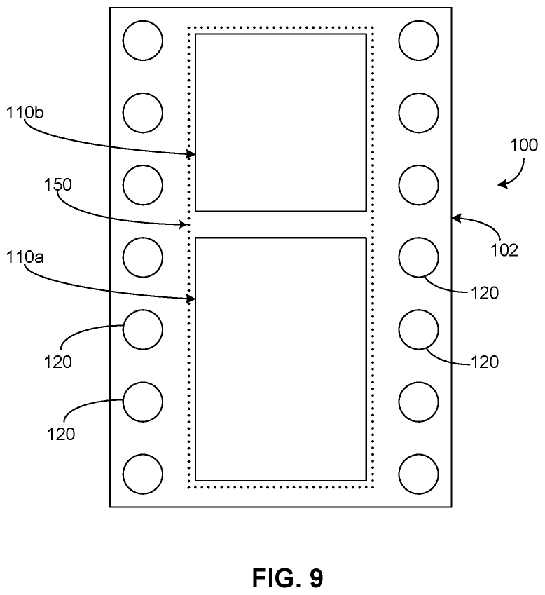

FIG. 9 is similar to the example of FIG. 8, but shows two underside components (e.g., die) 110a, 110b mounted within an increased mountable area 150. Thus, one can see that an increased mountable area as described herein can provide significantly more flexibility in design considerations, such as die size, number of die, arrangement of die, etc.

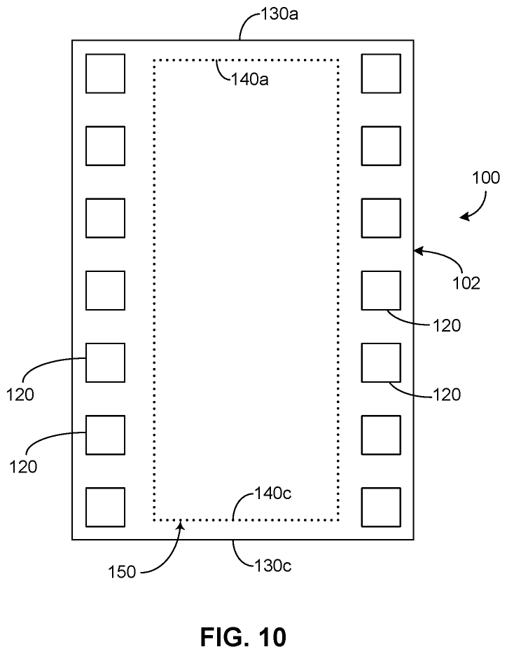

The various examples of FIGS. 3-9 are described in the context of solder balls. It will be understood that in some embodiments, other structures can be utilized. For example, FIG. 10 shows an underside of a packaging substrate 102 having an increased mountable area 150 similar to the example of FIG. 3. In FIG. 10, however, pillars 120 (e.g., columns, posts, etc.) are utilized instead of solder balls.

In some embodiments, a packaging substrate assembly and related module having one or more features as described herein can be utilized in a wireless application where relatively small number of signal(s) is/are being processed. For example, in some cellular low-bands (LBs), a given module only needs to process a few number of signals; thus, some grounding solder balls are not necessary. Accordingly, a pin (solder ball) assignment of connections of such a module can be configured so that a solder ball-less side correspond to some or all of such un-necessary grounding connections.

In some embodiments, a packaged module having one or more features can be fabricated utilizing, for example, some or all of the manufacturing techniques described in the above-referenced PCT Publication No. WO/2018/067578.

In some implementations, a packaged module having one or more features as described herein can be utilized in various products, including the examples described in the above-referenced PCT Publication No. WO/2018/067578.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. A packaged module comprising:
a packaging substrate having side edges;
a grid array arranged on an underside of the packaging substrate and including a plurality of mounting features arranged in at least two rows, each row along the respective side edge of the packaging substrate, such that at least one side edge of the packaging substrate is without a row of mounting features; and
a component mounted to the underside of the packaging substrate and within a mountable area defined by the at least two rows of mounting features and the at least one side edge of the packaging substrate without the row of mounting features.

2. The packaged module of claim 1 wherein the grid array is a ball grid array.

3. The packaged module of claim 2 wherein the mounting features include solder balls.

4. The packaged module of claim 1 wherein the mounting features include conductive pillars.

5. The packaged module of claim 4 wherein the conductive pillars include conductive columns or conductive posts.

6. The packaged module of claim 1 wherein the at least two rows of mounting features include two opposing rows along the two opposing side edges of the packaging substrate.

7. The packaged module of claim 6 wherein the at least one side edge of the packaging substrate without mounting features includes either or both of the other two opposing side edges of the packaging substrate.

8. The packaged module of claim 1 wherein the at least two rows of mounting features include two adjacent rows along the corresponding adjacent side edges of the packaging substrate.

9. The packaged module of claim 1 further comprising a radio-frequency circuit implemented in one or more semiconductor die mounted on an upper side of the packaging substrate.

10. The packaged module of claim 9 wherein the radio-frequency circuit is configured to support one or more low-band cellular frequency ranges.

11. (canceled)

12. (canceled)

13. The packaged module of claim 1 wherein the component mounted to the underside of the packaging substrate includes a die.

14. A method for fabricating a packaged module, the method comprising:
providing or forming a packaging substrate having side edges;
forming a grid array on an underside of the packaging substrate, such that the grid array includes a plurality of mounting features arranged in at least two rows, each row along the respective side edge of the packaging substrate, such that at least one side edge of the packaging substrate is without a row of mounting features; and
mounting a component to the underside of the packaging substrate and within a mountable area defined by the at least two rows of mounting features and the at least one side edge of the packaging substrate without the row of mounting features.

15. The method of claim 14 wherein forming of the grid array includes forming a ball grid array.

16. (canceled)

17. (canceled)

18. A packaging substrate assembly comprising:
a packaging substrate having side edges; and
a grid array arranged on an underside of the packaging substrate and including a plurality of mounting features arranged in at least two rows, each row along the respective side edge of the packaging substrate, such that at least one side edge of the packaging substrate is without a row of mounting features.

19. The packaging substrate assembly of claim 18 wherein the grid array is a ball grid array.

20. The packaging substrate assembly of claim 19 wherein the mounting features include solder balls.

21. The packaging substrate assembly of claim 18 wherein the mounting features include conductive pillars.

22. The packaging substrate assembly of claim 21 wherein the conductive pillars include conductive columns or conductive posts.

23. The packaging substrate assembly of claim 18 wherein the at least two rows of mounting features include two opposing rows along the two opposing side edges of the packaging substrate.

24. The packaging substrate assembly of claim 18 wherein the at least two rows of mounting features include two adjacent rows along the corresponding adjacent side edges of the packaging substrate.
